(19) United States
(12) Patent Application Publication
(10) Pub. No.: US 2013/0164435 A1
(43) Pub. Date: Jun. 27, 2013

(54) METHOD FOR TREATING AN ELASTOMERIC SURFACE OF A DEVICE FOR DISPENSING A FLUID PRODUCT

(71) Applicants: Marie Legoguelin, Rouen (FR); Patrice Leone, Acquigny (FR); Denis Busardo, Gonneville Sur Mer (FR); Frédéric Guernalec, Liffre (FR)

(72) Inventors: Marie Legoguelin, Rouen (FR); Patrice Leone, Acquigny (FR); Denis Busardo, Gonneville Sur Mer (FR); Frédéric Guernalec, Liffre (FR)

(73) Assignee: APTAR FRANCE SAS, Le Neubourg (FR)

(21) Appl. No.: 13/807,890

(22) PCT Filed: Jul. 1, 2011
(86) PCT No.: PCT/FR2011/051540

§ 371 Date: Mar. 8, 2013

(30) Foreign Application Priority Data
Jul. 2, 2010 (FR) 1055358
Jul. 8, 2010 (FR) 1002868

(51) Int. Cl. C23C 14/48

(52) U.S. Cl. CPC C23C 14/48
USPC 427/2.1; 427/525

(57) ABSTRACT

A method of treating an elastomer surface of a fluid dispenser device, said method comprising a step of modifying at least one elastomer surface to be treated of said device by ionic implantation using multi-charged and multi-energy ion beams, said modified elastomer surface limiting adhesion of the elastomer surfaces during the manufacturing and/or assembly stages, said multi-charged ions being selected from helium (He), nitrogen (N), oxygen (O), neon (Ne), argon (Ar), krypton (Kr), and xenon (Xe), ionic implantation being carried out to a depth of 0 μm to 3 μm.

The present invention relates to a method of treating an elastomer surface of a fluid dispenser device.

Fluid dispenser devices are well known. They generally comprise a reservoir, a dispenser member such as a pump or a valve, and a dispenser head provided with a dispenser orifice. Elastomer parts, such as gaskets, present certain disadvantages, in particular during the manufacturing and assembly stages. Thus, to avoid adhesion that might block a manufacturing and/or assembly line, gaskets must be talced, washed, and dried. These processes complicate the manufacture and assembly of the dispenser devices concerned. Similar problems can occur with other elastomer parts, e.g. pump pistons.

The aim of the present invention is to propose a method of treating an elastomer surface, in particular a gasket, that overcomes the disadvantages mentioned above.

In particular, the present invention is intended to provide a method of treating an elastomer surface that is effective, durable, non-polluting, and simple to carry out.

In particular, the invention provides a method of treating an elastomer polymer part by multi-charged and multi-energy ions belonging to the list constituted by helium (He), nitrogen (N), oxygen (O), neon (Ne), argon (Ar), krypton (Kr), and xenon (Xe), this polymer part forming a portion of a device for dispensing a fluid, in particular a pharmaceutical.

The majority of commercially available polymers do not conduct electric current. Their surface resistivity is in the range 10¹⁵Ω/□ [ohm per square] to 10¹⁷Ω/□.

However, electrical conduction may be desired for a number of reasons, including:
an antistatic effect: a reduction in the surface resistivity that lasts for weeks or months may be sufficient;
dissipation of electrostatic charges: this is accomplished by means of dissipative materials and conductors that prevent electrical discharges and that dissipate the charges resulting from high speed movements;
electromagnetic shielding: materials with a very low volume resistivity (<1 ohm·cm [ohm-centimeter]) are required. Standards must be complied with in order to limit electromagnetic emissions from manufactured products.

Conductivity may be obtained by various routes:
non-permanent additives, such as fatty acid esters or quaternary amines. When incorporated into a polymer matrix, such substances migrate to the surface and react with the moisture in the air. They reduce the surface resistivity to approximately 10¹⁴Ω/□ by forming a moist film on the surface;
fillers that reduce surface resistivity and volume resistivity permanently. In particular, these are carbon blacks, carbon fibers, graphite, stainless steel fibers, aluminum flakes, and carbon nanotubes. Such fillers increase polymer manufacturing costs excessively when only superficial antistatic or electrostatic charge dissipation electrical properties are required;
intrinsically conductive polymers. These are both expensive and sensitive to conditions of use. Heat and moisture rapidly degrade their electrical properties.

Adhesion is a significant phenomenon with polymers that results, for example, in the active agent adhering to a surface. Such adhesion results from the contribution of Van der Waals forces produced by the polarity of molecules located at the surface of the polymer and by the electrostatic forces induced by the very high surface resistivity.

In addition to problems with adhesion, polymer parts often need to function in chemical media of greater or lesser aggressivity, in ambient humidity, with ambient oxygen, etc., that may cause an increase in their electrically insulating nature by oxidation.

Certain polymers are filled with chemical agents for providing protection against UV or oxidation. Ejection of such chemical agents to the outside has the effect of accelerating surface oxidation, which in turn reinforces the insulating nature of the polymer.

The invention aims to reduce the above-mentioned disadvantages, in particular to substantially reduce the surface resistivity of a solid elastomer polymer part while retaining its bulk elastic properties and avoiding the use of chemical agents that are harmful to health.

Thus, the invention provides a method of treating at least one surface of a solid elastomer polymer part with helium ions, the method being characterized in that multi-energy ions X⁺ and X²⁺ are simultaneously implanted, where X belongs to the list constituted by helium (He), nitrogen (N), oxygen (O), neon (Ne), argon (Ar), krypton (Kr), and xenon (Xe), and where the ratio RX═X⁺/X²⁺, with X⁺ and X²⁺ being expressed as an atomic percentage, is less than or equal to 100, for example less than 20.

By way of example, the inventors have been able to establish that the simultaneous presence of He⁺ and He²⁺ ions can very significantly improve the antistatic surface properties of elastomer polymers compared with known treatments where only He⁺ or He²⁺ ions are implanted. They have been able to demonstrate that a significant improvement is observed for RHe less than or equal to 100, for example less than or equal to 20.

It should be noted that the invention can be used to reduce the surface resistivity of a solid elastomer polymer part and/or to eliminate dust or other adhesion, or even to reduce surface polarization by removing highly polarized chemical groups such as OH or COOH. Those functional groups may induce Van der Waals forces, which have the effect of bonding ambient chemical molecules to the polymer surface.

The invention can also be used to increase the chemical stability of the polymer, for example by creating a barrier to permeation. This can slow down the propagation of ambient oxygen within the polymer, and/or can retard the outward diffusion of agents contained in the polymer for protecting it against chemicals, and/or can inhibit leaching of toxic agents contained in the polymer towards the outside.

Advantageously, the invention can be used to dispense with adding chemical agents or fillers and to replace them with a physical method that is applicable to any type of polymer and that is less costly as regards material and energy consumption.

In the context of the present invention, the term “solid” means a polymer part produced by mechanical or physical transformation of a block of material, for example by extrusion, molding, or any other technique that is suitable for transforming a polymer block.

Because of the method of the present invention, much greater depths can be treated, resulting in high chemical stability, resulting in very long-term preservation of surface electrical properties (antistatic, electrostatic charge dissipation).

The treatment times have been shown to be not long, having regard to industrial requirements.

Further, the method is low energy, low cost, and can be used in an industrial context without any environmental impact.

An elastomer polymer part is treated by simultaneously implanting multi-energy, multi-charged ions. These are in particular obtained by extracting single- and multi-charged ions created in the plasma chamber of an electron cyclotron resonance ion source (ECR source) using a single extraction voltage. Each ion produced by said source has an energy that is proportional to its charge state. This results in ions with the highest charge state, and thus the highest energy, being implanted in the polymer part at the greatest depths.

Implantation with an ECR source is rapid and inexpensive since it does not require a high extraction voltage for the ion source. In fact, in order to increase the implantation energy of an ion, it is economically preferable to increase its charge state rather than to increase its extraction voltage.

It should be noted that a conventional source such as a source that provides for the implantation of ions by plasma immersion or filament implanters cannot be used to obtain a beam that is adapted to the simultaneous implantation of multi-energy ions X⁺ and X²⁺ where the ratio RX is less than or equal to 100. With such sources, in contrast, it is generally 1000 or higher.

The inventors have been able to establish that this method can be used to surface treat an elastomer polymer part without altering its bulk elastic properties.

In accordance with one implementation of the present invention, the source is an electron cyclotron resonance source producing multi-energy ions that are implanted in the part at a temperature of less than 50° C.; the ions from the implantation beam are implanted simultaneously at a controlled depth depending on the extraction voltage of the source.

Without wishing to be bound by a particular scientific theory, in the method of the invention, as they pass through, the ions could be considered to excite the electrons of the polymer, causing covalent bonds to break and immediately recombine in order to result in a high density of covalent chemical bonds primarily constituted by carbon atoms by means of a mechanism known as cross-linking. Lighter elements such as hydrogen and oxygen are evacuated from the polymer during degassing. This densification into carbon-rich covalent bonds has the effects of increasing surface conductivity and of reducing or even completely removing the polar surface groups at the origin of the Van der Waals forces that are the source of adhesion. The cross-linking process is even more effective if the ion is light.

Helium is thus an advantageous projectile that is favored because:
it is very fast compared with the speed of the electrons of the covalent bonds, and it is thus very effective in exciting those same electrons, which as a consequence do not have time to modify their orbitals;
it penetrates to large depths of micrometer order;
it is not dangerous;
because it is a noble gas, it has no effect on the chemical composition of the polymer.

Other types of ions that are easy to use without any health risks may be envisaged, such as nitrogen (N), oxygen (O), neon (Ne), argon (Ar), krypton (Kr), or xenon (Xe).

Various preferred implementations of the method of the present invention are possible and may be combined together. A preferred implementation consists, for example, in combining:
the ratio RHe, where RHe═He⁺/He²⁺, where He⁺ and He²⁺ are expressed as an atomic percentage, is greater than or equal to 1;
the extraction voltage of the source for implantation of the multi-energy ions He⁺ and He²⁺ is in the range 10 kV [kilovolts] to 400 kV, for example greater than or equal to 20 kV and/or less than or equal to 100 kV;
the dose of multi-energy ions He⁺ and He²⁺ is in the range 5×10¹⁴ ions/cm² to 10¹⁸ ions/cm², for example greater than or equal to 10¹⁵ ions/cm² and/or less than or equal to 5×10¹² ions/cm², or even greater than or equal to 5×10¹⁵ ions/cm² and/or less than or equal to 10¹⁷ ions/cm²;
in a previous step, the variation as a function of doses of multi-energy ions He⁺ and He²⁺ in a characteristic property of the change in the surface of a solid polymer part is determined, for example the surface resistivity of the polymer of a polymer material that is representative of the part to be treated, in order to determine a range of ion doses in which the variation in the selected characteristic property is advantageous and varies in different ways in three consecutive zones of ion doses forming said ion dose range, with a change in the first zone that is substantially linear and reversible over a period of less than one month, a change in the second zone that is substantially linear and stable over a period of more than one month, and finally a change in the third zone that is constant and stable over a period of more than one month, and in which the dose of multi-energy He⁺ and He²⁺ ions in the third ion dose zone is selected for treatment of the solid polymer part; the term “reversible change” (first zone) means that the resistivity reduces, then rises to regain its original value. This phenomenon is due to the persistence of free radicals after implantation, which recombine with oxygen in the ambient air, thus causing an increase in the surface resistivity;
the parameters of the source and of the movement of the surface of the polymer part to be treated are adjusted such that the speed of the surface treatment of the surface of the polymer part to be treated is in the range 0.5 cm²/s [square centimeter per second] to 1000 cm²/s, for example greater than or equal to 1 cm²/s and/or less than or equal to 100 cm²/s;
the parameters of the source and of the movement of the surface of the polymer part to be treated are adjusted such that the implanted helium dose is in the range 5×10¹⁴ to 10¹⁸ ions/cm², for example greater than or equal to 5×10¹⁵ ions/cm² and/or less than or equal to 10¹⁷ ions/cm²;
the parameters of the source and of the movement of the surface of the polymer part to be treated are adjusted such that the penetration depth of the helium on the surface of the treated polymer part is in the range 0.05 μm to 3 μm, for example greater than or equal to 0.1 μm and/or less than or equal to 2 μm;
the parameters of the source and of the movement of the surface of the polymer part to be treated are adjusted such that the surface temperature of the polymer part during treatment is less than or equal to 100° C., for example less than or equal to 50° C.;
the part to be treated is, for example, a profiled strip, and said part runs in a treatment device, for example at a speed in the range 5 m/min [meter per minute] to 100 m/min; by way of example, the part to be treated is a profiled strip that runs longitudinally;
helium is implanted from the surface of the part to be treated by means of a plurality of multi-energy He⁺ and He²⁺ ion beams produced by a plurality of ion sources; by way of example, the ion sources are disposed in the direction of movement of the part to be treated; preferably, the sources are spaced such that the distance between two ion beams is sufficient to allow the part to cool between each successive ion implantation; said sources produce ion beams with a diameter that is adapted to the width of the tracks to be treated. By reducing the diameter of the beams to 5 mm [millimeter], for example, it is possible to place a highly effective differential vacuum system between the source and the treatment chamber, meaning that the polymers can be treated at 10⁻² mbar [millibar], while the vacuum in the source extraction system is 10⁻⁶ mbar.

The invention also relates to a part wherein the thickness to which the helium is implanted is greater than or equal to 50 nm [nanometer], for example greater than or equal to 200 nm, and wherein the surface resistivity ρ is less than or equal to 10¹⁴Ω/□, for example less than or equal to 10⁹Ω/□, or even less than or equal to 10⁵Ω/□. Reference should be made to IEC standard 60093 for the measurement of surface resistivity.

Thus, the present invention provides a method of treating an elastomer surface of a fluid dispenser device, said method comprising a step of modifying at least one elastomer surface to be treated of said device by ionic implantation using multi-charged and multi-energy ion beams, said modified elastomer surface limiting adhesion of the elastomer surfaces during the manufacturing and/or assembly stages, said multi-charged ions being selected from helium (He), nitrogen (N), oxygen (O), neon (Ne), argon (Ar), krypton (Kr), and xenon (Xe), ionic implantation being carried out to a depth of 0 μm to 3 μm.

Advantageous implementations are described in the dependent claims.

In particular, said method comprises treating at least one surface of a solid elastomer polymer part with ions, said method comprising ionic bombardment with an ion beam constituted by multi-energy ions X⁺ and X²⁺, where X is the atomic symbol of the ion selected from the list comprising helium (He), nitrogen (N), oxygen (O), neon (Ne), argon (Ar), krypton (Kr), and xenon (Xe), in which RX═X⁺/X²⁺ with X⁺ and X²⁺, expressed as an atomic percentage, is less than or equal to 100, for example less than 20, in which the movement speed of the beam is determined in a previous step in which the lowest movement speed of the beam that does not cause thermal degradation of the polymer, manifested by an increase in pressure of 10⁻⁵ mbar, is identified.

These characteristics and advantages, along with others of the present invention, become clearer from the following detailed description made in particular with reference to the accompanying drawings given by way of non-limiting example, and in which:

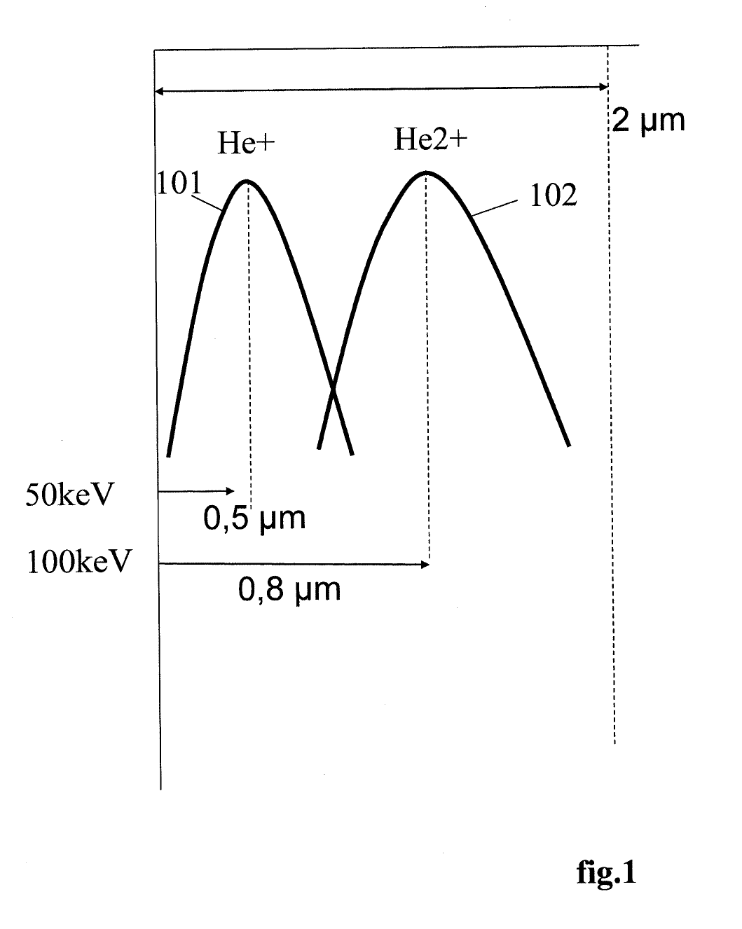

FIG. 1 shows an example of the distribution of the helium implantation of the invention in a polycarbonate;

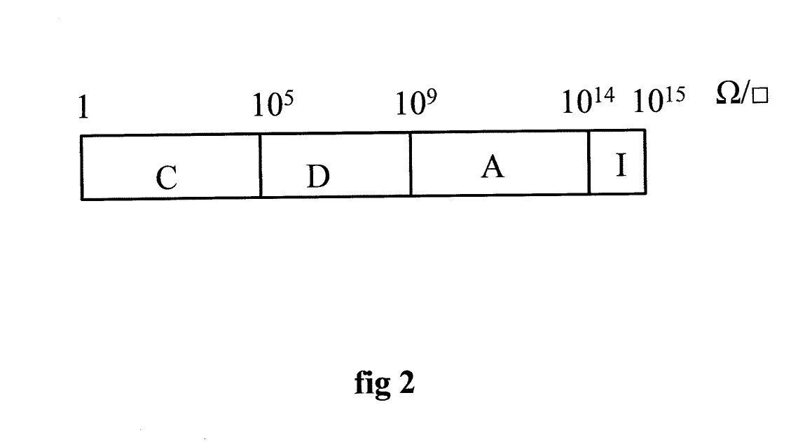

FIG. 2 shows the scales for various standards qualifying the electrostatic properties of a material;

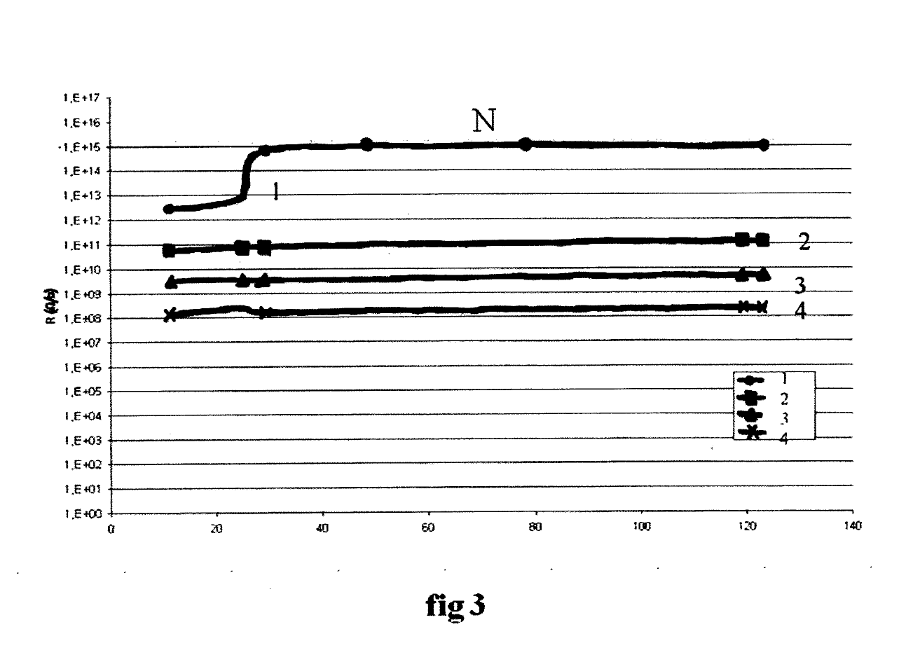

FIG. 3 shows the variation in the surface resistivity of the surface of a polycarbonate sample treated in accordance with the invention, as a function of time, for a plurality of helium doses; the surface resistivity was measured using IEC standard 60093 employing an electrode constituted by a disk with diameter d surrounded by a ring with internal diameter D, where D is more than d;

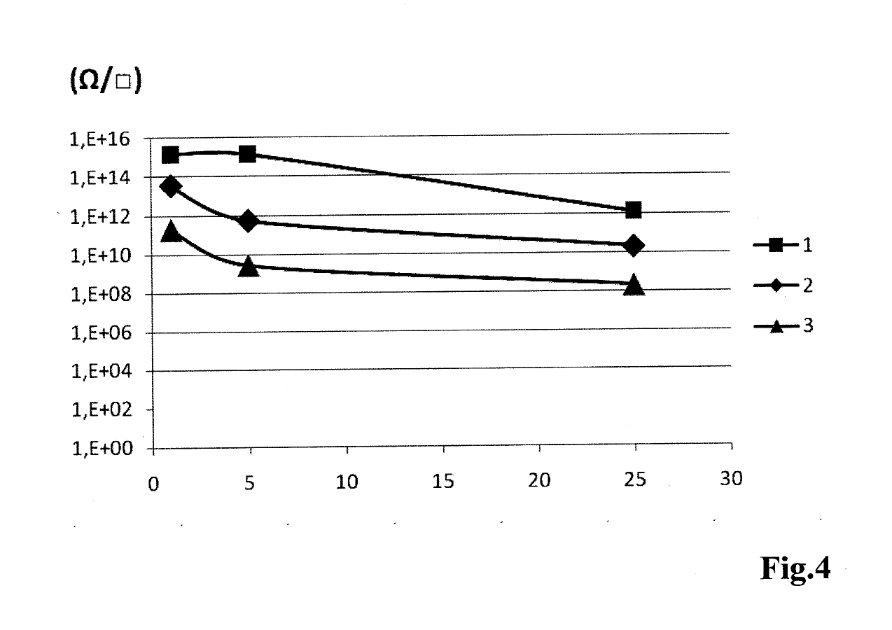

FIG. 4 shows the variation in the surface resistivity of the surface of a polycarbonate sample treated in accordance with the invention, as a function of time, for three types of ions He, N, Ar in a plurality of doses; the surface resistivity was measured using IEC standard 60093; and

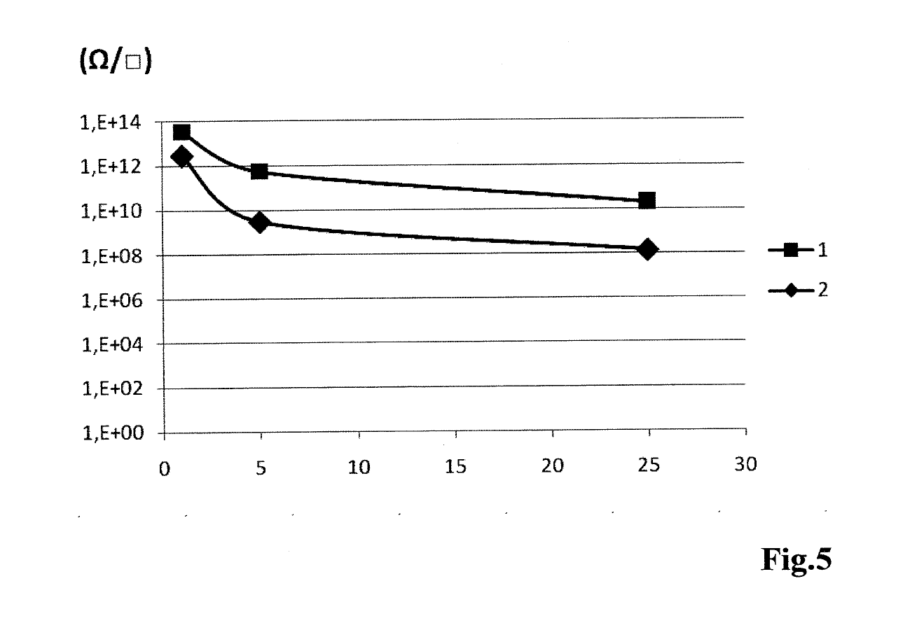

FIG. 5 shows the variation in surface resistivity of the surface of a polycarbonate sample treated in accordance with the invention, as a function of time, for a plurality of doses of nitrogen but using two beam movement speeds; the surface resistivity was measured using IEC standard 60093.

In particular, the present invention provides for using a method similar to that described in document WO 2005/085491, which relates to an ionic implantation method, and more particularly to the use of a beam of multi-charged multi-energy ions, in order to structurally modify the surfaces of metallic materials over depths of about a μm in order to provide them with particular physical properties. That implantation method has in particular been used to treat parts produced from an aluminum alloy that are used as molds for the mass production of plastics material parts.

Surprisingly, that type of method has proved to be suitable for avoiding elastomer surfaces adhering to one another, in particular during the manufacture of fluid dispenser device gaskets. Such an application of that ionic implantation method has never been envisaged before. It avoids the talcing operations that are usually necessary during the manufacture and assembly of gaskets for fluid dispenser devices. Thus, the description of that document WO 2005/085491 is incorporated in its entirety into the present description for the purposes of reference.

The elastomer surface is preferably a neck gasket or a valve gasket of a dispenser device for dispensing a pharmaceutical. The gasket may be made of any appropriate elastomer material, such as ethylene-propylene terpolymer rubber (EPDM), chloroprene, nitrile rubber, hydrogenated nitrile butadiene rubber (HNBR), etc.

Put simply, the method consists of using one or more sources of ions such as an electron cyclotron resonance source, termed an ECR source. This ECR source can deliver an initial beam of multi-energy ions, for example with a total current of approximately 10 mA [milliamp] (all charges together) at an extraction voltage that may lie in the range 20 kV to 200 kV. The ECR source emits a beam of ions in the direction of adjustment means that focus and adjust the initial beam emitted by the ECR source into a beam of implantation ions that strike a part to be treated. Depending on the applications and the materials to be treated, the ions may be selected from helium, boron, carbon, nitrogen, oxygen, neon, argon, krypton, and xenon. Similarly, the maximum temperature of the part to be treated varies as a function of its nature. The typical implantation depth is in the range 0 μm to 3 μm, and depends not only on the surface to be treated but also on the properties that are to be improved.

The specificity of a source of ECR ions resides mainly in the fact that it delivers single- and multi-charged ions, meaning that multi-energy ions can be implanted simultaneously with the same extraction voltage. It is thus possible to obtain a properly distributed implantation profile over the whole of the treated thickness simultaneously. This improves the quality of the surface treatment.

Advantageously, the method is carried out in a chamber that is evacuated by means of a vacuum pump. This vacuum is intended to prevent interception of the beam by residual gasses and to prevent contamination of the surface of the part by those same gasses during implantation.

Advantageously, and as described in particular in document WO 2005/085491, the adjustment means mentioned above may comprise the following elements, from the ECR source to the part to be treated:
a mass spectrometer that can filter ions as a function of their charge and their mass. Such a spectrometer is optional, however, if a pure gas is injected, for example pure nitrogen gas (N2). Thus, it is possible to recover all of the single- and multi-charged ions produced by the source in order to obtain a multi-energy ion beam;
one or more lenses to provide the ion beam with a predetermined shape, for example cylindrical, with a predetermined radius;
a profiler in order to analyze the intensity of the beam in a perpendicular sectional plane during the first implantation;
an intensity transformer in order to measure the intensity of the ion beam continuously without intercepting it. This instrument primarily detects any interruptions in the ion beam and makes it possible to record variations in the intensity of the beam during the treatment;
a shutter that may, for example, be a Faraday cage, to interrupt the trajectory of the ions at certain moments, for example during movement without treating the part.

In an advantageous implementation, the part to be treated is movable relative to the ECR source. The part may, for example, be mounted on a movable support that is used under the control of an N/C [numerically controlled] machine. The movement of the part to be treated is calculated as a function of the radius of the beam, the external and internal contours of the zones to be treated, the constant or variable movement speed as a function of the angle of the beam relative to the surface and the number of passes already carried out.

One possible implementation of the treatment method is as follows. The part to be treated is fixed on an appropriate support in a chamber, then the chamber is closed and an intense vacuum is set up using a vacuum pump. As soon as the vacuum conditions are reached, the ion beam is started up and adjusted. When said beam has been adjusted, the shutter is lifted and the N/C machine is actuated, which machine then controls the position and the speed of the movement of the part to be treated in front of the beam in one or more passes. When the number of passes required has been reached, the shutter is dropped to cut off the beam, beam production is halted, the vacuum is broken by opening the chamber to the ambient air, the cooling circuit is switched off if appropriate, and the treated part is removed from the chamber.

In order to reduce the temperature linked to the passage of the ion beam at a given point of the part to be treated, either the radius of the beam can be increased (to reduce the power per cm²), or the movement speed can be increased. If the part is too small to evacuate the heat associated with treatment by irradiation, either the power of the beam can be reduced (i.e. the treatment period is increased), or the cooling circuit is started up.

Concerning elastomers in particular, it is advantageous to simultaneously implant multi-energy helium ions He⁺ and He²⁺. This is described in particular in document PCT/FR2010/050379, which is hereby incorporated by reference, which more particularly relates to the treatment of windshield wiper blades for vehicles. Advantageously, the ratio RHe, where RHe═He⁺/He²⁺, where He⁺ and He²⁺ are expressed as atomic percentages, is less than or equal to 100, for example less than 20, and preferably more than 1. The He⁺ and He²⁺ ions are advantageously simultaneously produced by one ECR source. The extraction voltage of the source allowing the implantation of multi-energy He⁺ and He²⁺ ions may be in the range 10 kV to 400 kV, for example greater than or equal to 20 kV and/or less than or equal to 100 kV. Advantageously, the dose of multi-energy He⁺ and He²⁺ ions is in the range 10¹⁴ to 10¹⁸ ions/cm², for example greater than or equal to 10¹⁵ ions/cm² and/or less than or equal to 10¹⁷ ions/cm², or even greater than or equal to 10¹⁵ ions/cm² and/or less than or equal to 10¹⁶ ions/cm². The implantation depth is advantageously in the range 0.05 μm to 3 μm, for example in the range 0.1 μm to 2 μm. The temperature of the elastomer surface during treatment is advantageously less than 100° C., preferably less than 50° C.

In an advantageous implementation of the invention, different ionic implantations are carried out in the same elastomer surface to be treated in order to produce several properties in this elastomer surface to be treated. Thus, the elastomer surfaces, and in particular the above-mentioned gaskets, could interact with the fluid, e.g. by leaching extractables into said fluid, and this could have a harmful effect on said fluid. Advantageously, the invention can be used to modify the elastomer surface by ionic implantation in order to prevent interactions between the elastomer surface and the fluid. It is also possible to envisage modifying the elastomer surface by ionic implantation so as to impart anti-friction properties thereto, in particular so as to make it easier for pistons and valve members to move in the gaskets. Other complementary treatments can also be envisaged, in particular so as to improve the ability to withstand oxidation, wear, and/or abrasion. These additional surface treatments may be applied during successive ionic implantations. It should be noted that these successive ionic implantations may be carried out in any order. In a variation, the various properties could also be applied to the same surface to be treated during one and the same ionic implantation step.

The method of the invention is non-polluting, in particular because it does not require chemicals. It is carried out dry, and so it avoids the relatively long drying periods associated with liquid treatment methods. It does not require there to be a sterile atmosphere outside the vacuum chamber; thus, it can be carried out anywhere. A particular advantage of this method is that it can be integrated into the assembly line for the fluid dispenser device and operated continuously in that line. This integration of the treatment method in the production tool simplifies and speeds up the manufacturing and assembly process as a whole and thus has a positive impact on its cost.

FIGS. 1 to 5 illustrate advantageous implementations of the invention.

FIG. 1 shows a diagrammatic example of the implantation distribution of helium as a function of depth in accordance with the invention, in a polycarbonate. The following description applies equally to elastomer polymers. Curve 101 corresponds to the distribution of He⁺ and curve 102 to that of He²⁺. It can be estimated that for energies of 100 keV, He²⁺ covers a mean distance of approximately 800 nm for a mean ionization energy of 10 eV/Å [electron-volts per Ångström]. For energies of 50 keV, He⁺ covers a mean distance of approximately 500 nm for a mean ionization energy of 4 eV/Å. The ionization energy of an ion is related to its cross-linking power. When (He⁺/He²⁺) is less than or equal to 100, it can be estimated that the maximum treated thickness is of the order of 1000 nm, i.e. 1 micrometer. These estimates agree with observations carried out by electron microscopy, which have demonstrated that for a beam extracted at 40 kV and a total dose of 5×10¹⁵ ions/cm² and (He⁺/He²⁺)=10, a cross-linked layer of approximately 750 nm to 850 nm is observed.

FIG. 2 shows the resistivity values qualifying the electrostatic properties of a material, in accordance with standard DOD HDBK 263. A polymer has insulating properties for surface resistivity values of more than 10¹⁴Ω/□ (ZONE I), and antistatic properties for values of surface resistivity in the range 10¹⁴Ω/□ to 10⁹Ω/□(zone A). Electrostatic charge dissipation properties appear for values of surface resistivity in the range 10⁵Ω/□ to 10⁹Ω/□(zone D) and conductive properties appear for values of less than 10⁵Ω/□(zone C).

FIG. 3 shows the experimental change in surface resistivity of a polycarbonate as a function of time for different doses of helium equal to 10¹⁵ (curve 1), 2.5×10¹⁵ (curve 2), 5×10¹⁵ ions/cm² (curve 3), 2.5×10¹⁶ ions/cm² (curve 4), with He⁺/He²⁺=10; the extraction voltage is approximately 40 kV. The resistivity measurement was carried out in accordance with IEC standard 60093. The resistivity measurement technique employed did not allow resistivities of more than 10¹⁵Ω/□ to be measured, corresponding to zone N; it was saturated at 10¹⁵Ω/□. The abscissa corresponds to the time between the sample being treated and its surface resistivity being measured. The ordinate corresponds to the measurement of the surface resistivity, expressed in Ω/□. A first zone can be observed for doses of less than or equal to 10¹⁵ ions/cm², where the surface resistivity reduces over less than one month by approximately 3 orders of magnitude (from 1.5×10¹⁶Ω/□ to 5×10¹²Ω/□) before regaining its original value of about 1.5×10¹⁶Ω/□ (curve 1). In this zone, the antistatic properties are ephemeral, the free radicals still present recombining with oxygen in ambient air. In a second zone, the resistivity can be seen to decline as a function of dose: over the range 2.5×10¹⁵ ions/cm², 5×10¹⁵ ions/cm², 2.5×10¹⁶ ions/cm², the surface resistivity reduces from 10¹¹Ω/□ to 5×10⁹Ω/□ until it reaches a saturation plateau estimated to be at about 1.5×10⁸Ω/□. The antistatic properties (curves 2 and 3) are reinforced to become capable of dissipating electrostatic charges (curve 4). For these doses, the resistivities remained constant for more than 140 days. For doses of more than 2.5×10¹⁶ ions/cm², a third zone is reached where the change in resistivity saturates, as a function of dose, at about a value that is estimated to be 10⁸Ω/□ and remains stable over time for more than 140 days.

FIG. 4 shows the experimental change in surface resistivity of a polycarbonate (PC) as a function of time for three types of ions: He (curve 1), N (curve 2) and Ar (curve 3) for various doses equal to 10¹⁵ ions/cm², 5×10¹⁵ ions/cm², and 2.5×10¹⁶ ions/cm², with (He⁺/He²⁺)=10, (N⁺/N²⁺)=2 and (Ar⁺/Ar²⁺)=1.8. The beam diameter was 15 mm and the current was 0.225 mA; the extraction voltage was approximately 35 kV. The abscissa represents the dose in ions per unit surface area, expressed in 10¹⁵ ions/cm². The ordinate represents the surface resistivity, expressed in Ω/□. The resistivity measurement was carried out in accordance with IEC standard 60093. For the same dose, the heaviest ions were the most effective in reducing the surface resistivity; the PC treated with nitrogen had a surface resistivity at least 10 times lower than that of the PC treated with helium, the PC treated with argon had a surface resistivity at least ten times lower than that of the PC treated with helium. The inventors recommend using even heavier ions such as xenon to further reduce the surface resistivity of polycarbonate.

FIG. 5 shows the experimental change in the surface resistivity of a polycarbonate as a function of time for the same type of ions but at two different beam movement speeds—a movement speed of 80 mm/s (curve 1), a movement speed of 40 mm/s (curve 2)—for different doses equal to 10¹⁵ ions/cm², 5×10¹⁵ ions/cm², and 2.5×10¹⁶ ions/cm² (N⁺/N²⁺)=2. The beam diameter was 15 mm and the current was 0.150 mA; the extraction voltage was approximately 35 kV. The abscissa represents the dose in ions per unit surface area, expressed in 10¹⁵ ions/cm². The ordinate represents the surface resistivity, expressed in Q/□. The resistivity measurement was carried out in accordance with IEC standard 60093. From these curves, it appears that reducing speed by a factor of 2 has the effect of reducing the surface resistivity of the PC by a factor of 10. Without wishing to be bound by any particular scientific theory, it could be considered that by reducing the speed of the beam, the surface temperature of the PC is increased. This temperature greatly increases recombination of free radicals between one another, at the same time favoring the formation of a dense, conductive film of amorphous carbon. Heating also has the effect of expelling residual gases produced by the scission/cross-linking mechanisms induced by ionic bombardment. The inventors deduced from this experiment that for any polymer treated with a beam with a known diameter and power, there exists a minimum beam movement speed causing a maximum reduction in surface resistivity of the polymer without risking degradation of the polymer under the effect of the heat produced. Thermal degradation of the polymer is indicated by substantial degassing followed by an increase in the pressure in the extraction system for the ECR source. This increase in pressure manifests itself in electrical breakdowns. The extraction system acts to extract ions from the plasma of the ECR source to form the beam. It is constituted by two electrodes, the first being earthed, and the second being brought to a high voltage of several tens of kV (kilovolts) under vacuum conditions of less than 5×10⁻⁶ mbar, preferably less than 2×10⁻⁶ mbar. Beyond these pressures, electric arcs are produced. This happens when thermal degradation of the polymer occurs. These rises in pressure should therefore be detected very early on by gradually reducing the beam movement speed and monitoring the change in pressure in the extraction system.

In order to determine this beam movement speed, the inventors recommend a test step that consists in gradually reducing the beam speed while retaining the other characteristics:
the beam characteristic: diameter, power, in other words intensity, and extraction voltage;
dynamic characteristics: amplitude of movement, rate of advance.

The polymer degrades thermally under the effect of heat when the pressure rise measured by a gauge located both in the extraction system and in the treatment chamber jumps by 10⁻⁵ mbar in a few seconds or even less. The tests must be stopped immediately to retain only the movement speed of the beam in the preceding test. This jump of 10⁻⁵ mbar in a few seconds or even less constitutes the signature of thermal degradation of the polymer.

Several characterization methods have allowed the advantages of the present invention to be highlighted.

In the examples below, the treatment of at least one surface of a solid polymer part by implantation of helium ions He⁺ and He²⁺ was carried out with multi-energy He⁺ and He²⁺ ions produced simultaneously by a ECR source. The treated polymers were the following in particular: polypropylene (PP), and polymethylacrylate (PMMA).

Comparative tests relating to the antistatic properties using small pieces of paper thrown onto the treated samples demonstrated that this appears for doses of more than 5×10¹⁵ ions/cm². For these doses, the pieces of paper detached and fell off when these samples were turned over, which did not happen for doses of less than 5×10¹⁵ ions/cm².

For polypropylene, a surface resistivity of 10¹⁴Ω/□ could be measured in accordance with IEC standard 60093 and for doses of 10¹⁵ ions/cm² and 5×10¹⁵ ions/cm². For a dose of 2×10¹⁶ ions/cm², it was possible to measure a resistivity of 5×10¹¹Ω/□, corresponding to the appearance of these antistatic properties.

In one implementation, it was estimated that the surface antistatic properties of a polymer were significantly improved from a dose of more than 5×10¹⁵ ions/cm², which represents a treatment speed of approximately 15 cm²/s for a helium beam constituted by 9 mA He⁺ ions and 1 mA He²⁺ ions.

The simultaneous implantation of helium ions may be carried out to various depths as a function of the requirements and shape of the part to be treated. These depths are in particular dependent on the implantation energies of the ions of an implantation beam; they may, for example, be from 0.1 μm to approximately 3 μm for a polymer. For applications where non-stick properties are desired, for example, a thickness of less than a micrometer would suffice, for example, further reducing the treatment period.

In one implementation, the conditions for implanting He⁺ and He²⁺ ions are selected such that the polymer part retains its bulk elastic properties by keeping the part at treatment temperatures of less than 50° C. This result may in particular be achieved for a beam with a diameter of 4 mm, delivering a total current of 60 microamps, with an extraction voltage of 40 kV, being moved at 40 mm/s over movement amplitudes of 100 mm. This beam has a power per unit surface area of 20 W/cm² [watt per square centimeter]. When using the same extraction voltage and the same power per unit surface area, and beams with a higher intensity while retaining the bulk elastic properties, a rule of thumb can be drawn up that consists in increasing the diameter of the beam, increasing the movement speed and increasing the amplitudes of the movements in a ratio corresponding to the square root of the desired current divided by 60 μA [microamps]. As an example, for a current of 6 milliamps (i.e. 100 times 60 microamps), the beam should have a diameter of 40 mm in order to keep the power per unit surface area at 20 W/cm². Under these conditions, the speed can be multiplied by a factor of 10 and the movement amplitudes by a factor of 10, which gives a speed of 40 cm/s and movement amplitudes of 1 m. The number of passes may also be multiplied by the same factor in order to have the same treatment dose expressed in ions/cm² in the end. With continuous running, the number of microaccelerators placed on the path of a belt, for example, may be multiplied by the same ratio.

It can also be seen that other surface properties are very significantly improved by means of a treatment in accordance with the invention; performance has been achieved that does not appear to have been attained with other techniques.

The invention is not limited to these types of implementations and should be interpreted in a non-limiting manner, encompassing treating any type of polymer.

Similarly, the method of the invention is not limited to the use of an ECR source, and even if it could be thought that other sources would be less advantageous, the method of the invention may be carried out with single-ion sources or with other multi-ion sources, as long as the sources are configured so as to allow simultaneous implantation of multi-energy ions belonging to the list constituted by helium (He), nitrogen (N), oxygen (O), neon (Ne), argon (Ar), krypton (Kr), and xenon (Xe).

Various modifications are also possible for the skilled person without departing from the scope of the present invention as defined in the accompanying claims.

1. A method of treating an elastomer surface of a fluid dispenser device, comprising a step of modifying at least one elastomer surface to be treated of said device by ionic implantation using multi-charged and multi-energy ion beams, said modified elastomer surface limiting adhesion of the elastomer surfaces during the manufacturing and/or assembly stages, said multi-charged ions being selected from helium (He), nitrogen (N), oxygen (O), neon (Ne), argon (Ar), krypton (Kr), and xenon (Xe), ionic implantation being carried out to a depth of 0 μm to 3 μm.

2. A method according to claim 1, wherein said multi-energy ions are implanted simultaneously with the same extraction voltage.

3. A method according to claim 1, wherein multi-energy helium ions He⁺ and He²⁺ are implanted simultaneously.

4. A method according to claim 3, wherein the ratio RHe, where RHe═He⁺/He²⁺, where He⁺ and He²⁺ are expressed as atomic percentages, is less than or equal to 100, for example less than 20, and more than 1.

5. A method according to claim 1, wherein the temperature of the elastomer surface during treatment is less than 100° C., preferably less than 50° C.

6. A method according to claim 1, wherein said modified elastomer surface has antistatic properties.

7. A method according to claim 1, wherein said method comprises treating at least one surface of a solid elastomer polymer part with ions, said method comprising ionic bombardment with an ion beam constituted by multi-energy ions X⁺ and X²⁺, where X is the atomic symbol of the ion selected from the list comprising helium (He), nitrogen (N), oxygen (O), neon (Ne), argon (Ar), krypton (Kr), and xenon (Xe), wherein RX═X⁺/X²⁺, with X⁺ and X²⁺, expressed as atomic percentages, being less than or equal to 100, for example less than 20, and wherein the movement speed of the beam is determined in a previous step in which the lowest movement speed of the beam is identified that does not cause thermal degradation of the polymer, as manifested by an increase in pressure of 10⁻⁵ mbar.

8. A method according to claim 7, wherein the ions X⁺ and X²⁺ are produced simultaneously by an electron cyclotron resonance ion source (ECR).

9. A method according to claim 7, wherein the ratio RX is greater than or equal to 1.

10. A method according to claim 7, wherein the extraction voltage of the source allowing implantation of multi-energy ions X⁺ and X²⁺ is in the range 10 kV to 400 kV, for example greater than or equal to 20 kV and/or less than or equal to 100 kV.

11. A method according to claim 7, wherein the dose of multi-energy ions X⁺ and X²⁺ is in the range 5×10¹⁴ ions/cm² to 10¹⁸ ions/cm², for example greater than or equal to 10¹⁵ ions/cm² and/or less than or equal to 5×10¹⁷ ions/cm² or even greater than or equal to 5×10¹⁵ ions/cm² and/or less than or equal to 10¹⁷ ions/cm².

12. A method according to claim 7, wherein in a previous step, the variation as a function of the dose of multi-energy ions X⁺ and X²⁺ in a characteristic property of the change of the surface of a solid polymer part, for example the electrical resistivity of the surface, ρ, of a polymer material representative of that of the part to be treated, is determined in order to determine a range of ion doses wherein the variation in the selected characteristic property is advantageous and varies in different ways in three consecutive zones of ion doses forming said ion doses range, with a change in the first zone that is substantially linear and reversible over a period of less than one month, a change in the second zone that is substantially linear and stable over a period of more than one month, and finally a change in the third zone that is constant and stable over a period of more than one month, and wherein the dose of multi-energy ions X⁺ and X²⁺ in the third ion dose zone is selected to treat the solid polymer part.

13. A method according to claim 7, wherein the parameters of the source and of the movement of the surface of the polymer part to be treated are adjusted such that the areal speed of the surface of the polymer part to be treated is in the range 0.5 cm²/s to 1000 cm²/s, for example greater than or equal to 1 cm²/s and/or less than or equal to 100 cm²/s.

14. A method according to claim 7, wherein the parameters of the source and of the movement of the surface of the polymer part to be treated are adjusted such that the implanted ion dose is in the range 5×10¹⁴ ions/cm² to 10¹⁸ ions/cm², for example greater than or equal to 5×10¹⁵ ions/cm² and/or less than or equal to 10¹⁷ ions/cm².

15. A method according to claim 7, wherein the parameters of the source and of the movement of the surface of the polymer part to be treated are adjusted such that the penetration depth of the ion on the surface of the treated polymer part is in the range 0.05 μm to 3 μm, for example greater than or equal to 0.1 μm and/or less than or equal to 2 μm.

16. A method according to claim 7, wherein the parameters of the source and of the movement of the surface of the polymer part to be treated are adjusted such that the temperature of the surface of the polymer part during treatment is less than or equal to 100° C., for example less than or equal to 50° C.

17. A method according to claim 7, wherein the polymer part to be treated runs past a treatment device, for example at a speed in the range 5 m/min to 100 m/min.

18. A method according to claim 7, wherein ion implantation from the surface of the polymer part to be treated is carried out by means of a plurality of multi-energy beams of X⁺ and X²⁺ ions produced by a plurality of ion sources.

19. A method according to claim 1, wherein the method further comprises an ionic implantation step of providing said surface to be treated with at least one additional property such as a reduction of interactions between the modified elastomer surface and the fluid, such as the leaching of extractables.

20. A method according to claim 1, wherein said dispenser device comprises a reservoir containing the fluid, a dispenser member such as a pump or a valve attached to said reservoir, and a dispenser head provided with a dispenser orifice in order to actuate said dispenser member.

21. A method according to claim 1, wherein said elastomer surface is a neck gasket and/or a valve gasket of a dispenser member, such as a pump or a valve.

22. A method according to claim 1, wherein said fluid is a pharmaceutical fluid for spraying and/or inhaling nasally or orally.

23. A method according to claim 1, wherein said method is carried out continuously on an assembly line for the fluid dispenser device.
